(19) United States
(12) Patent Application Publication
(10) Pub. No.: US 2024/0276778 A1
(43) Pub. Date: Aug. 15, 2024

(54) Display Substrate, Preparing Method Therefor, and Display Apparatus

(71) Applicants: Hefei Xinsheng Optoelectronics Technology Co., Ltd., Hefei, Anhui (CN); BOE Technology Group Co., Ltd., Beijing (CN)

(72) Inventors: Ning LIU, Beijing (CN); Yang ZHANG, Beijing (CN); Haitao WANG, Beijing (CN); Zhengchao ZHANG, Beijing (CN); Bin ZHOU, Beijing (CN); Liangchen YAN, Beijing (CN)

(21) Appl. No.: 18/023,730

(22) PCT Filed: Apr. 26, 2022
(86) PCT No.: PCT/CN2022/089256

§ 371 Date: Feb. 28, 2023

(51) Int. Cl. H10K 59/122; H10K 59/12; H10K 59/131; H10K 59/80; H10K 102/00

(52) U.S. Cl. CPC H10K 59/122; H10K 59/1201; H10K 59/131; H10K 59/80522; H10K 2102/351

(57) ABSTRACT

The present disclosure provides a display substrate and a preparation method thereof, and a display apparatus. The display substrate comprises a display region and a transparent region, and on a plane perpendicular to the display substrate, the display substrate at least comprises a drive structure layer and a light-emitting structure layer which are arranged on a substrate, wherein the drive structure layer at least comprises an inorganic insulation layer, and the light-emitting structure layer at least comprises a pixel definition layer; the drive structure layer of the display region further comprises a planarization layer arranged on the inorganic insulation layer, and a pixel definition layer is arranged on the planarization layer and is in contact with the planarization layer; and at least one groove is provided on the inorganic insulation layer of the transparent region, and the pixel definition layer fills the groove located in the transparent region.

### CROSS-REFERENCE TO RELATED APPLICATION

The present application is a U.S. National Phase Entry of International PCT Application No. PCT/CN2022/089256, having an international filing date of Apr. 26, 2022, the entire content of which is hereby incorporated by reference.

### TECHNICAL FIELD

The present disclosure relates to, but is not limited to, the field of display technologies, and in particular to a display substrate, a method for preparing the display substrate, and a display apparatus.

### BACKGROUND

An Organic light-emitting Diode (OLED for short) and a Quantum dot light-emitting Diode (QLED for short) are active light-emitting display devices and have advantages such as self-luminescence, a wide viewing angle, a high contrast ratio, low power consumption, extremely high response speed, lightness and thinness, flexibility, and low cost. With continuous development of display technologies, a display apparatus using the OLED or the QLED as a light-emitting device and using a Thin Film Transistor (TFT) for signal control has become a mainstream product in the field of display at present.

### SUMMARY

The following is a summary of subject matters described herein in detail. The summary is not intended to limit the protection scope of claims.

In one aspect, the present disclosure provides a display substrate, including a display region configured to achieve image display and a transparent region configured to make light pass through; on a plane perpendicular to a display substrate, the display substrate at least includes a drive structure layer arranged on a substrate and a light-emitting structure layer arranged on a side of the drive structure layer away from the substrate, wherein the drive structure layer at least includes an inorganic insulation layer, and the light-emitting structure layer at least includes a pixel definition layer; the drive structure layer of the display region further includes a planarization layer arranged on a side of the inorganic insulation layer away from the substrate, and the pixel definition layer is arranged on a side of the planarization layer away from the substrate and is in contact with the planarization layer; and at least one groove is arranged on the inorganic insulation layer in the transparent region, and the pixel definition layer fills the groove located in the transparent region.

In an exemplary embodiment, a thickness of the pixel definition layer in the transparent region is greater than a thickness of the pixel definition layer in the display region.

In an exemplary embodiment, a depth of the groove is less than a thickness of the inorganic insulation layer.

In an exemplary embodiment, a depth of the groove is equal to a thickness of the inorganic insulation layer.

In an exemplary embodiment, the drive structure layer of the transparent region at least includes a buffer layer arranged on the substrate and an interlayer insulation layer arranged on a side of the buffer layer away from the substrate, the inorganic insulation layer is arranged on a side of the interlayer insulation layer away from the substrate, and the pixel definition layer filling the groove is in contact with the interlayer insulation layer.

In an exemplary embodiment, the groove includes a first groove and a second groove which are communicated, wherein the second groove is arranged on a groove bottom of the first groove, and an orthographic projection of the second groove on the substrate is located within the range of an orthographic projection of the first groove on the substrate.

In an exemplary embodiment, on a plane parallel to the display substrate, a shape of the groove includes any one or more of the following: triangle, rectangle, polygon, circle and ellipse.

In an exemplary embodiment, on a plane perpendicular to the substrate, a cross-sectional shape of the groove is in a shape of a rectangle, a trapezoid or a polygon.

In an exemplary embodiment, the inorganic insulation layer is provided with a plurality of grooves, wherein the plurality of grooves are identical in shape or different in shape on a plane parallel to the substrate.

In an exemplary embodiment, a plurality of grooves are provided on the inorganic insulation layer, and the plurality of grooves have the same size or different sizes on a plane parallel to the substrate.

In an exemplary embodiment, a plurality of grooves are provided on the inorganic insulation layer, and the plurality of grooves have the same depth or different depths in a plane perpendicular to the substrate.

In an exemplary embodiment, an anode via is also provided on the inorganic insulation layer of the display region; on a plane parallel to the substrate, an area of the orthographic projection of the groove on the plane of the substrate is greater than an area of the orthographic projection of the anode via on the plane of the substrate.

In an exemplary embodiment, an auxiliary cathode is further provided on the transparent region, and the auxiliary cathode is arranged on a side of the groove away from the display region.

In an exemplary embodiment, the auxiliary cathode includes a first auxiliary cathode arranged on a side of the inorganic insulation layer away from the substrate, a second auxiliary cathode arranged on a side of the first auxiliary cathode away from the substrate, and a third auxiliary cathode arranged on a side of the second auxiliary cathode away from the substrate, wherein an orthographic projection of the second auxiliary cathode on the substrate is located within a range of an orthographic projection of the first auxiliary cathode on the substrate, and the orthographic projection of the second auxiliary cathode on the substrate is located within a range of an orthographic projection of the third auxiliary cathode on the substrate.

In an exemplary embodiment, the pixel definition layer covers an edge of the auxiliary cathode close to a side of the display region.

In another aspect, the present disclosure further provides a display apparatus, including the aforementioned display substrate.

In yet another aspect, the present disclosure further provides a method for preparing a display substrate, the display substrate comprising a display region and a transparent region, wherein the display region is configured to achieve image display, and the transparent region is configured to make light pass through; the preparing method comprises:
forming a drive structure layer on the substrate, wherein the drive structure layer at least comprises an inorganic insulation layer, the drive structure layer of the display region further comprises a planarization layer arranged on a side of the inorganic insulation layer away from the substrate, and at least one groove is arranged on the inorganic insulation layer in the transparent region; and
forming a light-emitting structure layer on the drive structure layer, wherein the light-emitting structure layer at least includes a pixel definition layer, the pixel definition layer is arranged on a side of the planarization layer away from the substrate and is in contact with the planarization layer, and the pixel definition layer fills a groove located in the transparent region.

Other aspects may be understood upon reading and understanding the drawings and detailed description.

### BRIEF DESCRIPTION OF DRAWINGS

Accompanying drawings are used for providing further understanding of technical solutions of the present disclosure, constitute a part of the specification, and together with the embodiments of the present disclosure, are used for explaining the technical solutions of the present disclosure but not to constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display substrate;

FIG. 2 is a schematic diagram of a planar structure of a display substrate;

FIG. 3 is a schematic diagram of a sectional structure of a display substrate;

FIG. 4 is a schematic diagram of an equivalent circuit of a pixel drive circuit;

FIG. 5 is a schematic diagram of a planar structure of a display substrate according to an exemplary embodiment of the present disclosure;

FIG. 6 is a schematic diagram of a sectional structure of a display substrate according to an exemplary embodiment of the present disclosure.

FIG. 7A to FIG. 7C are schematic diagrams of a planar structure of the groove according to an exemplary embodiment of the present disclosure;

FIG. 8A to FIG. 8C are schematic diagrams of a sectional structure of the groove according to an exemplary embodiment of the present disclosure;

FIG. 9 is a schematic diagram of the display substrate after a pattern of a circuit layer of a transistor is formed according to an embodiment of the present disclosure;

FIG. 10 is a schematic diagram of the display substrate obtained after a pattern of a fourth insulation layer is formed according to an embodiment of the present disclosure;

FIG. 11 is a schematic diagram of the display substrate obtained after a pattern of a first planarization layer is formed according to an embodiment of the present disclosure;

FIG. 12 is a schematic diagram of the display substrate after a pattern of an anode conductive layer is formed according to an embodiment of the present disclosure;

FIG. 13 is a schematic diagram of a display substrate after a pattern of a pixel definition layer is formed according to an embodiment of the present disclosure;

FIG. 14 is a schematic structural diagram of the display substrate after patterns of an organic light-emitting layer and a cathode are formed according to the present disclosure.

### DESCRIPTION OF REFERENCE SIGNS

| | | |
|---|---|---|
| 10-substrate; | 11-first insulation layer; | 12-second insulation |
| | | layer; |
| 13-third insulation layer; | 14-fourth insulation | 15-first planarization |
| | layer; | layer; |
| 20-drive structure layer; | 21-anode; | 21-1-first anode; |
| 21-2-second anode; | 21-3-third anode; | 22-pixel definition layer; |
| 23-organic light-emitting | 24-cathode; | 30-light-emitting |
| layer; | | structure layer; |
| 40-encapsulation | 51-shielding electrode; | 52-active layer; |
| structure layer; | | |
| 53-gate electrode; | 54-source electrode; | 55-drain electrode; |
| 60-power supply | 70-auxiliary cathode; | 70-1-first auxiliary |
| electrode; | | cathode; |
| 70-2-second auxiliary | 70-3-third auxiliary | 80-groove; |
| cathode; | cathode; | |
| 81-first groove; | 82-second groove; | 91-emitting block; |
| 92-cathode block; | 100-display region; | 200-transparent region; |
| 210-transition region; | 300-display unit; | |

### DETAILED DESCRIPTION

To make objectives, technical solutions, and advantages of the present disclosure clearer, the embodiments of the present disclosure will be described in detail with reference to the accompanying drawings. It is to be noted that implementations may be implemented in a plurality of different forms. Those of ordinary skills in the art may easily understand such a fact that implementations and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other without conflict. In order to keep following description of the embodiments of the present disclosure clear and concise, detailed descriptions about part of known functions and known components are omitted in the present disclosure. The drawings of the embodiments of the present disclosure only involve structures involved in the embodiments of the present disclosure, and other structures may refer to usual designs.

Scales of the drawings in the present disclosure may be used as a reference in the actual process, but are not limited thereto. For example, the width-length ratio of the channel, the thickness and spacing of each film layer, and the width and spacing of each signal line may be adjusted according to actual needs. The number of pixels in the display substrate and the number of sub-pixels in each pixel are not limited to the numbers shown in the drawings. The drawings described in the present disclosure are schematic structure diagrams only, and one implementation of the present disclosure is not limited to the shapes, numerical values or the like shown in the drawings.

Ordinal numerals such as “first”, “second”, and “third” in the specification are set to avoid confusion of constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. It may be a mechanical connection or an electrical connection. It may be a direct mutual connection, or an indirect connection through middleware, or internal communication between two components. Those of ordinary skill in the art may understand specific meanings of these terms in the present disclosure according to specific situations.

In the specification, a transistor refers to a component which includes at least three terminals, i.e., a gate electrode, a drain electrode and a source electrode. The transistor has a channel region between the drain electrode (drain electrode terminal, drain region, or drain) and the source electrode (source electrode terminal, source region, or source), and a current may flow through the drain electrode, the channel region, and the source electrode. It is to be noted that, in the specification, the channel region refers to a region through which the current mainly flows.

In the specification, a first electrode may be a drain electrode, and a second electrode may be a source electrode. Or, the first electrode may be the source electrode, and the second electrode may be the drain electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes a case that constituent elements are connected together through an element with a certain electrical effect. The “element with the certain electrical effect” is not particularly limited as long as electrical signals may be sent and received between the connected constituent elements. Examples of the “element with the certain electrical effect” not only include electrodes and wirings, but also include switch elements such as transistors, resistors, inductors, capacitors, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon and hexagon in this specification are not strictly defined, and they may be approximate triangle, rectangle, trapezoid, pentagon or hexagon, etc. There may be some small deformation caused by tolerance, and there may be chamfer, arc edge and deformation, etc.

In the present disclosure, “about” refers to that a boundary is defined not so strictly and numerical values within process and measurement error ranges are allowed.

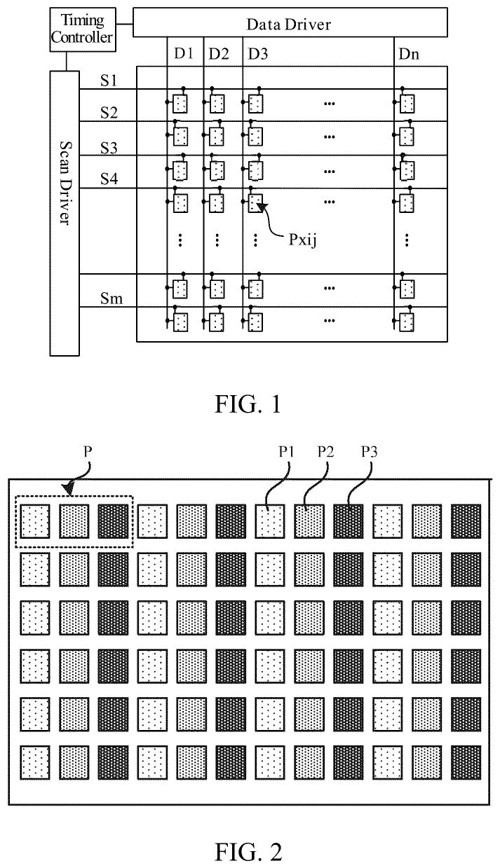

FIG. 1 is a schematic diagram of a structure of a display apparatus. Referring to FIG. 1, an OLED display apparatus may include a timing controller, a data driver, a scan driver, and a pixel array. The pixel array may include a plurality of scan signal lines (S1 to Sm), a plurality of data signal lines (D1 to Dn), and a plurality of sub-pixels Pxij. In an exemplary embodiment, the timing controller may provide a control signal and a gray scale value suitable for the specification of the data driver to the data driver, and may provide a scan start signal, a clock signal suitable for the specification of the scan driver and the like to the scan driver. The data driver may generate a data voltage to be provided to the data signal lines D1, D2, D3, . . . , and Dn by using the gray tone value and the control signal that are received from the timing controller. For example, the data driver may sample the gray scale value using the clock signal, and apply a data voltage corresponding to the gray scale value to the data signal lines D1 to Dn in a unit of a sub-pixel row, wherein n may be a natural number. The scan driver may receive the clock signal, the scan start signal, etc., from the timing controller to generate a scan signal to be provided to the scan signal lines S1, S2, S3, . . . , and Sm. For example, the scan driver may provide a scan signal with an on-level pulse to the scan signal lines S1 to Sm sequentially. For example, the scan driver may be constructed in a form of a shift register and may generate a scan signal in a manner in which the scan start signal provided in a form of an on-level pulse is transmitted to a next-stage circuit sequentially under the control of the clock signal, wherein m may be a natural number. An array of sub-pixels may include the plurality of sub-pixels PXij. Each sub-pixel PXij may be connected to a corresponding data signal line and a corresponding scan signal line, wherein i and j may be natural numbers. The sub-pixel Pxij may refer to a sub-pixel in which a transistor is connected to an i-th scan signal line and is connected to a j-th data signal line.

FIG. 2 is a schematic diagram of a planar structure of a display substrate. As shown in FIG. 2, the display substrate may include multiple pixel units P arranged in a matrix, at least one of the multiple pixel units P includes a first sub-pixel P1 emitting light of a first color, a second sub-pixel P2 emitting light of a second color, and a third sub-pixel P3 emitting light of a third color. The first sub-pixel P1, the second sub-pixel P2, and the third sub-pixel P3 each include a pixel drive circuit and a light-emitting device. The pixel drive circuit in the first sub-pixel P1, the second sub-pixel P2, and the third sub-pixel P3 is connected with a scan signal line, a data signal line, and a light-emitting signal line respectively. The pixel drive circuit is configured to receive a data voltage transmitted by the data signal line under control of the scan signal line and the light-emitting signal line, and output a corresponding current to the light-emitting device. Each light-emitting device in the first sub-pixel P1, the second sub-pixel P2, and the third sub-pixel P3 is connected with a pixel drive circuit of a sub-pixel where the light-emitting device is located, and is configured to emit light with corresponding brightness in response to a current output by the pixel drive circuit of the sub-pixel where the light-emitting device is located.

In an exemplary implementation, the first sub-pixel P1 may be a red sub-pixel (R) emitting red light, the second sub-pixel P2 may be a blue sub-pixel (B) emitting blue light, and the third sub-pixel P3 may be green sub-pixels (G) emitting green light. In an exemplary implementation, a shape of the sub-pixel may be a rectangle, a rhombus, a pentagon or a hexagon, and the three sub-pixels may be arranged side by side horizontally, side by side vertically, in a shape of a Chinese character “ [symbol] ”, which is not limited here in the present disclosure.

In other exemplary implementations, the pixel unit may include four sub-pixels, and the four sub-pixels may be arranged side by side horizontally, side by side vertically, in a square, or the like, which is not limited here in the present disclosure.

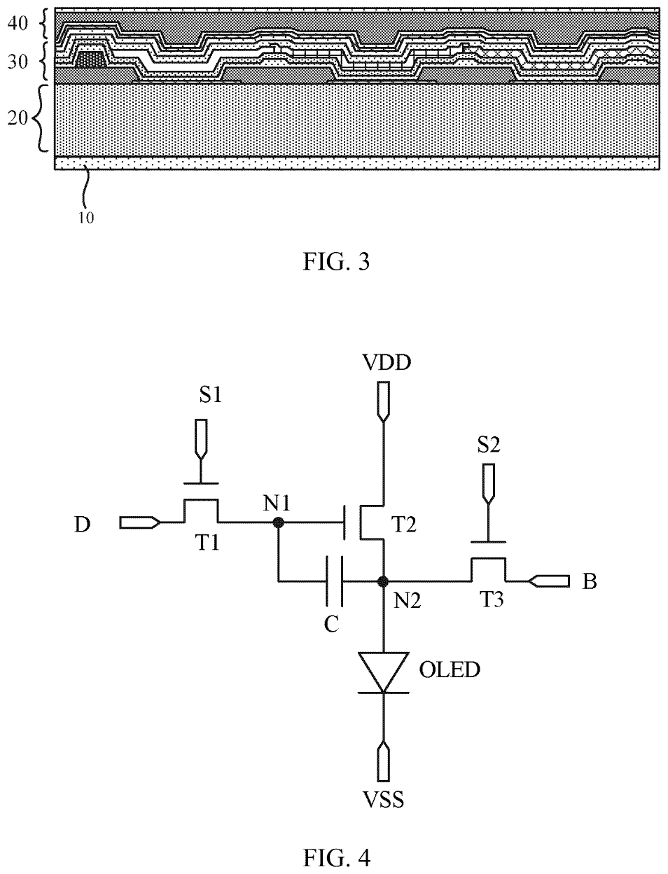

FIG. 3 is a schematic diagram of a cross-sectional structure of a display substrate, which illustrates a structure of three sub-pixels of an OLED display substrate. As shown in FIG. 3, in a plane perpendicular to the display substrate, the display substrate may include a drive structure layer 20 arranged on a substrate 10, a light-emitting structure layer 30 arranged at a side of the drive structure layer 20 away from the substrate 10, and an encapsulation structure layer 40 arranged at a side of the light-emitting structure layer 30 away from the substrate 10. In some possible implementations, the display substrate may include other film layers, such as a touch structure layer, which is not limited here in the present disclosure.

In an exemplary implementation, the substrate 10 may be a flexible substrate, or a rigid substrate. The drive structure layer 20 of each sub-pixel may include a plurality of transistors and storage capacitors forming a pixel drive circuit. The light-emitting structure layer 30 may include an anode, a pixel definition layer, an organic light-emitting layer and a cathode. The anode is connected with a drain electrode of the drive transistor through a via, the organic light-emitting layer is connected with the anode, the cathode is connected with the organic light-emitting layer, and the organic light-emitting layer emits light of corresponding color under the drive of the anode and the cathode. The encapsulation structure layer 40 may include a first encapsulation layer, a second encapsulation layer, and a third encapsulation layer that are stacked, the first encapsulation layer and the third encapsulation layer may be made through an inorganic material, the second encapsulation layer may be made through an organic material, and the second encapsulation layer is arranged between the first encapsulation layer and the third encapsulation layer to ensure that external water vapor cannot enter the light-emitting structure layer 30.

FIG. 4 is a schematic diagram of an equivalent circuit of a pixel drive circuit. In an exemplary implementation, the pixel drive circuit may be in a 3T1C, 4T1C, 5T1C, 5T2C, 6T1C, or 7T1C structure. As shown in FIG. 4, the pixel drive circuit has a 3T1C structure, which may include three switch transistors (a first transistor T1, a second transistor T2, and a third transistor T3), one storage capacitor C, and six signal lines (a data line D, a first scan line S1, a second scan line S2, a compensation line S, a first power supply line VDD, and a second power supply line VSS). In an exemplary implementation, the first transistor T1 is a switching transistor, the second transistor T2 is a drive transistor, and the third transistor T3 is a compensation transistor. A gate electrode of the first transistor T1 is coupled to the first scanning line S1, a first electrode of the first transistor T1 is coupled to the data line D, a second electrode of the first transistor T1 is coupled to a gate electrode of the second transistor T2. The first transistor T1 is configured to receive a data signal transmitted by the data line S1 under the control of the first scanning line D, so that the gate electrode of the second transistor T2 receives the data signal. The gate electrode of the second transistor T2 is coupled to the second electrode of the first transistor T1, a first electrode of the second transistor T2 is coupled to the first power supply line VDD, a second electrode of the second transistor T2 is coupled to a first electrode of an OLED, and the second transistor T2 is configured to generate a corresponding current at the second electrode under the control of the data signal received by the gate electrode of the second transistor. A gate electrode of the third transistor T3 is coupled to the second scan line S2, a first electrode of the third transistor T3 is coupled to the compensation line B, a second electrode of the third transistor T3 is coupled to the second electrode of the second transistor T2. The third transistor T3 is configured to extract a threshold voltage Vth and the mobility of the second transistor T2 in response to compensation timing to compensate the threshold voltage Vth. The first electrode of the OLED is coupled to the second electrode of the second transistor T2, a second electrode of the OLED is coupled to the second power supply line VSS, and the OLED is configured to emit light with corresponding brightness in response to the current of the second electrode of the second transistor T2. A first electrode of the storage capacitor C is coupled to the gate electrode of the second transistor T2, a second electrode of the storage capacitor C is coupled to the second electrode of the second transistor T2, and the storage capacitor C is configured to store a potential of the gate electrode of the second transistor T2.

In an exemplary implementation, a signal of the first power supply line VDD is a high-level signal continuously provided, and a signal of the second power supply line VSS is a low-level signal. The first transistor T1 to the third transistor T3 may be P-type transistors or may be N-type transistors. Use of a same type of transistors in a pixel drive circuit may simplify a process flow, reduce process difficulties of a display panel, and improve a product yield. In some possible implementations, the first transistor T1 to the third transistor T3 may include a P-type transistor and an N-type transistor.

In an exemplary implementation, the light-emitting device may be an organic light-emitting diode (OLED), including a first electrode (anode), an organic light-emitting layer and a second electrode (cathode) that are stacked.

According to a light-emitting direction, the OLED display substrates may be classified into three types, including a bottom emission OLED, a top emission OLED, and a double-sided emission OLED. The bottom emission OLED emits light from the bottom direction of the substrate, and the top emission OLED emits light from the top direction of the substrate. The double-sided emission OLED emits light from both the bottom direction of the substrate and the top direction of the substrate. Compared with the bottom emission OLED, the top emission OLED has advantages such as high aperture ratio, high color purity, and easiness in achieving high resolution, i.e., pixels per inch (PPI for short), and thus are widely used, especially for a display apparatus with larger size. Transparent display is an important personalized display field of display technology, which means that the image is displayed in a transparent state, and the viewer may not only see the image in the display apparatus, but also see the scene behind the display apparatus. It can be widely used in vehicle display such as cars/subways and window display such as hotels/clothing stores or the like, with obvious advantages such as clear image quality and realistic display effect.

The present disclosure provides a display substrate, including a display region configured to achieve image display and a transparent region configured to make light pass through; on a plane perpendicular to a display substrate, the display substrate at least includes a drive structure layer arranged on a substrate and a light-emitting structure layer arranged on a side of the drive structure layer away from the substrate, wherein the drive structure layer at least includes an inorganic insulation layer, and the light-emitting structure layer at least includes a pixel definition layer; the drive structure layer of the display region further includes a planarization layer arranged on a side of the inorganic insulation layer away from the substrate, and the pixel definition layer is arranged on a side of the planarization layer away from the substrate and is in contact with the planarization layer; and at least one groove is arranged on the inorganic insulation layer in the transparent region, and the pixel definition layer fills the groove located in the transparent region.

In an exemplary implementation, a thickness of the pixel definition layer in the transparent region is greater than a thickness of the pixel definition layer in the display region.

In an exemplary implementation, a depth of the groove is less than a thickness of the inorganic insulation layer.

In an exemplary implementation, a depth of the groove is equal to a thickness of the inorganic insulation layer.

In an exemplary implementation, the drive structure layer of the transparent region at least includes a buffer layer arranged on the substrate and an interlayer insulation layer arranged on a side of the buffer layer away from the substrate, the inorganic insulation layer is arranged on a side of the interlayer insulation layer away from the substrate, and the pixel definition layer filling the groove is in contact with the interlayer insulation layer.

In an yet another exemplary implementation, the groove includes a first groove and a second groove which are communicated, wherein the second groove is arranged on a groove bottom of the first groove, and an orthographic projection of the second groove on the substrate is located within the range of an orthographic projection of the first groove on the substrate.

In an exemplary implementation, on a plane parallel to the display substrate, a shape of the groove includes any one or more of the following: triangle, rectangle, polygon, circle and ellipse.

In an exemplary implementation, on a plane perpendicular to the substrate, a cross-sectional shape of the groove is in a shape of a rectangle, a trapezoid or a polygon.

In an exemplary implementation, the inorganic insulation layer is provided with a plurality of grooves, wherein the plurality of grooves are identical in shape or different in shape on a plane parallel to the substrate.

In an exemplary implementation, a plurality of grooves are provided on the inorganic insulation layer, and the plurality of grooves have the same size or different sizes on a plane parallel to the substrate.

In an exemplary implementation, a plurality of grooves are provided on the inorganic insulation layer, and the plurality of grooves have the same depth or different depths in a plane perpendicular to the substrate.

In an exemplary implementation, an anode via is also provided on the inorganic insulation layer of the display region; on a plane parallel to the substrate, an area of the orthographic projection of the groove on the plane of the substrate is greater than an area of the orthographic projection of the anode via on the plane of the substrate.

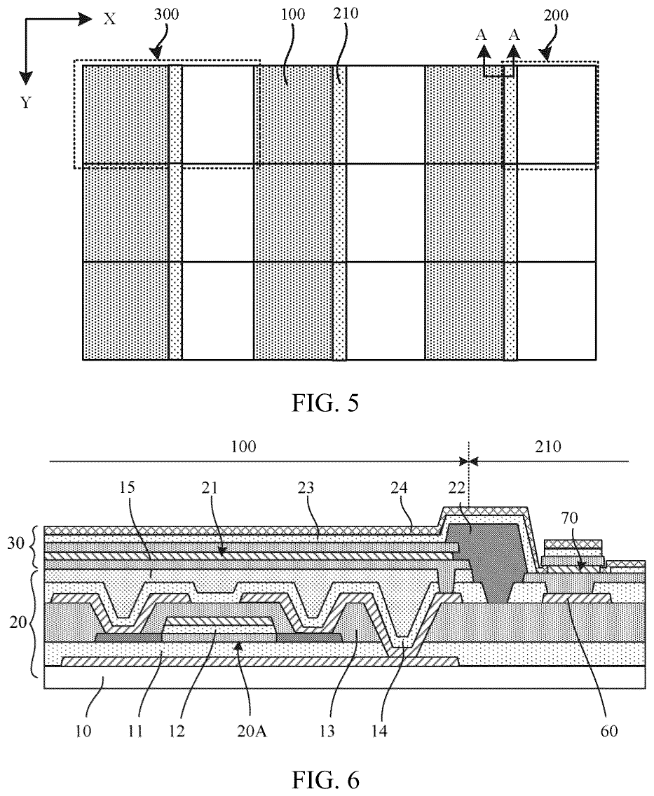

FIG. 5 is a schematic diagram of a planar structure of a display substrate according to an exemplary embodiment of the present disclosure. As shown in FIG. 5, on a plane parallel to the display substrate, the display substrate may include a plurality of display units 300 arranged regularly, and the plurality of display units 300 may form a plurality of unit rows and a plurality of unit columns, wherein the unit row may include a plurality of display units 300 sequentially arranged along a first direction X, the unit column may include a plurality of display units 300 sequentially arranged along a second direction Y, and the first direction X intersects with the second direction Y. At least one display unit 300 may include a display region 100 and a transparent region 200, wherein the transparent region 200 may be located on a side of the display region 100 in the first X, the display region 100 is configured to achieve image display, and the transparent region 200 is configured to make light pass through, thereby achieving image display in a transparent state, i.e., transparent display.

In an exemplary implementation, the transparent region 200 may at least include a transition region 210, wherein the transition region 210 may be located on a side of the transparent region 200 close to the display region 100, i.e. on a junction region between the display region 100 and the transparent region 200, and is configured to be provided with an auxiliary cathode.

FIG. 6 is a schematic diagram of a sectional structure of a display substrate according to an exemplary embodiment of the present disclosure, and is a cross-sectional view taken along a direction A-A in FIG. 5. As shown in FIG. 6, in an exemplary implementation, on a plane perpendicular to the display substrate, the display substrate may at least include a drive structure layer 20 arranged on the substrate 10, a light-emitting structure layer 30 arranged on a side of the drive structure layer 20 away from the substrate 10.

In an exemplary implementation, the drive structure layer 20 of the display region 100 may at least include a transistor 20A constituting the pixel drive circuit, and the light-emitting structure layer 30 of the display region 100 may at least include a light-emitting device connected to the transistor 20A.

In an exemplary implementation, on a plane perpendicular to the display substrate, the drive structure layer 20 of the display region 100 may at least include a first conductive layer, a first insulation layer 11, a semiconductor layer, a second insulation layer 12, a second conductive layer, a third insulation layer 13, a third conductive layer, a fourth insulation layer 14 and a planarization layer 15 which are arranged sequentially on the substrate 10, wherein the first conductive layer may at least include a shielding electrode, the semiconductor layer may at least include an active layer, the second conductive layer may at least include a gate electrode, the third conductive layer may at least include a source electrode and a drain electrode, the fourth insulation layer 14 and the planarization layer 15 are provided with anode vias, and the shielding electrode, the active layer, the gate electrode, the source electrode and the drain electrode may constitute the transistor 20A. The light-emitting structure layer 30 of the display region 100 may at least include an anode 21, a pixel definition layer 22, an organic light-emitting layer 23, and a cathode 24. The anode 21 may be arranged on a side of the planarization layer 15 away from the base, and may be connected with the drain electrode of the transistor 20A through a via. The pixel definition layer 22 may be arranged on a side of the anode 21 away from the substrate, and the pixel definition layer 22 is provided with a pixel opening that exposes a surface of the anode 21. The organic light-emitting layer 23 may be arranged on a side of the pixel definition layer 22 away from the substrate, the organic light-emitting layer 23 is connected with the anode 21 through the pixel opening, the cathode 24 may be arranged on a side of the organic light-emitting layer 23 away from the substrate, and the anode 21, the organic light-emitting layer 23 and the cathode 24 constitute the light-emitting device.

In an exemplary implementation, the drive structure layer 20 of the transition region 210 in the transparent region 200 may at least include a power supply electrode 60 and at least one groove, wherein the power supply electrode 60 may be arranged in the third conductive layer, the at least one groove may be arranged on the fourth insulation layer 14 that is used as an inorganic insulation layer, and the groove is configured to increase the contact area between the pixel definition layer 22 and the fourth insulation layer 14. The light-emitting structure layer 30 of the transition region 210 may at least include a pixel definition layer 22 and an auxiliary cathode 70, wherein the pixel definition layer 22 is arranged on a side of the fourth insulation layer 14 away from the substrate, the pixel definition layer 22 fills at least one groove, and the auxiliary cathode 70 is arranged on a side of the fourth insulation layer 14 away from the substrate, and is connected to the power supply electrode 60 through a via.

In an exemplary implementation, the source electrode and the drain electrode of the display region 100 and the power supply electrode 60 of the transition region 210 may be arranged in a same layer, are made through a same material, and are formed simultaneously through the same patterning process.

In an exemplary implementation, the anode 21 of the display region 100 and the auxiliary cathode 70 of the transition region 210 may be arranged in a same layer, are made through a same material, and are formed simultaneously through the same patterning process.

In an exemplary implementation, the light-emitting structure layer 30 of the transition region 210 may also include an organic light-emitting block and a cathode block, wherein the organic light-emitting block may be arranged on a side of the auxiliary cathode 70 away from the substrate, the organic light-emitting block and the organic light-emitting layer of the display region 100 may be arranged in a same layer, which are made through a same material and are formed simultaneously through the same patterning process, the cathode block may be arranged on a side of the organic light-emitting block away from the substrate, and the cathode block and the cathode of the display region 100 may be arranged in a same layer, which are made through a same material and are formed simultaneously through the same patterning process.

In an exemplary implementation, on a plane perpendicular to the display substrate, the transparent region 200 other than the transition region 210 may include a first insulation layer 11, a third insulation layer 13, and a fourth insulation layer 14 that are sequentially arranged on the substrate 10, and other film layers of the transparent region 200 (such as a planarization layer and a pixel definition layer) are removed to improve transparency.

In an exemplary implementation, in a plane parallel to the display substrate, a shape of the auxiliary cathode 70 may include any one or more of the following: triangle, square, rectangle, pentagon, hexagon, circle and ellipse.

In an exemplary implementation, in a plane perpendicular to the display substrate, the auxiliary cathode 70 may include a first auxiliary cathode 70-1, a second auxiliary cathode 70-2 arranged on a side of the first auxiliary cathode 70-1 away from the substrate, and a third auxiliary cathode 70-3 arranged on a side of the second auxiliary cathode 70-2 away from the substrate, wherein an orthographic projection of the second auxiliary cathode 70-2 on the substrate is located within an orthographic projection of the first auxiliary cathode 70-1 on the substrate, an orthographic projection of the second auxiliary cathode 70-2 on the substrate is located within an orthographic projection of the third auxiliary cathode 70-3 on the substrate, and the first auxiliary cathode 70-1, the second auxiliary cathode 70-2 and the third auxiliary cathode 70-3 which are stacked constitute a “ [symbol] ”-shaped auxiliary cathode structure.

In an exemplary implementation, on a plane perpendicular to the display substrate, the anode 21 may include a first anode 21-1, a second anode 21-2 arranged on a side of the first anode 21-1 away from the substrate, and a third anode 21-3 arranged on a side of the second anode 21-2 away from the substrate, wherein an orthographic projection of the second anode 21-2 on the substrate is located within an range of an orthographic projection of the first anode 21-1 on the substrate, and an orthographic projection of the second anode 21-2 on the substrate is located within an range of an orthographic projection of the third anode 21-3 on the substrate.

In an exemplary implementation, the first auxiliary cathode 70-1 and the first anode 21-1 may be arranged in a same layer, and are made through a same material.

In an exemplary implementation, the second auxiliary cathode 70-2 and the second anode 21-2 are arranged in a same layer, and are made through a same material.

In an exemplary implementation, the third auxiliary cathode 70-3 and the third anode 21-3 are arranged in a same layer, and are made through a same material.

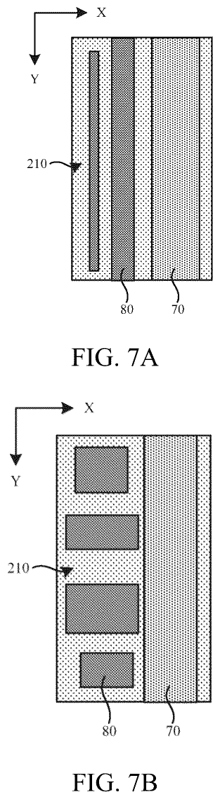

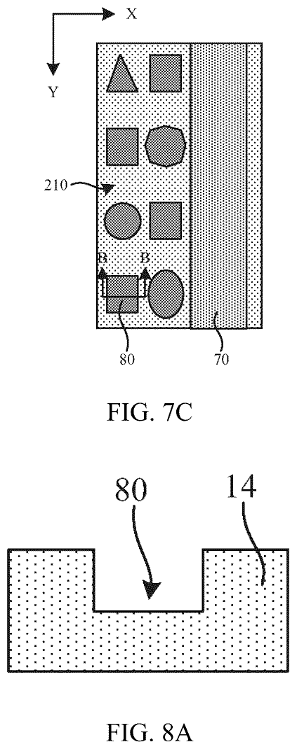

FIG. 7A to FIG. 7C are schematic diagrams of a planar structure of the groove according to an exemplary embodiment of the present disclosure, illustrating a planar structure of a transition region. In an exemplary implementation, the transition region 210 may include an auxiliary cathode 70 and at least one groove 80, wherein the auxiliary cathode 70 may be arranged on a side of the groove 80 away from the display region 100 (the side of the display region 100 in the first direction X).

In an exemplary implementation, on a plane parallel to the display substrate, a shape of the auxiliary cathode 70 may be a strip shape extending along the second direction Y, and a shape of the groove 80 may include any one or more of the following: triangle, rectangle, polygon, circle and ellipse.

In an exemplary implementation, on a plane parallel to the display substrate, a shape of the groove 80 may be a strip shape extending along the first direction X, or the shape of the groove 80 may be a strip shape extending along the second direction Y.

In an exemplary implementation, when a plurality of grooves 80 are arranged in the transition region, the plurality of grooves 80 may be sequentially arranged along the first direction X, as shown in FIG. 7A, or the plurality of grooves 80 may be sequentially arranged along the second direction Y as shown in FIG. 7B, or the plurality of grooves 80 may be sequentially arranged along the first direction X and the second direction Y, respectively, as shown in FIG. 7C.

In exemplary implementation, when a plurality of grooves 80 are arranged in the transition region, shapes of the plurality of grooves 80 may be the same, or may be different.

In exemplary implementation, when a plurality of grooves 80 are arranged in the transition region, widths of the plurality of grooves 80 may be the same, or may be different, and the widths may be the maximum size of the grooves in the first direction X.

In exemplary implementation, when a plurality of grooves 80 are arranged in the transition region, lengths of the plurality of grooves 80 may be the same, or may be different, and the lengths may be the maximum size of the grooves in the second direction Y.

In exemplary implementation, when a plurality of grooves 80 are arranged in the transition region, depths of the plurality of grooves 80 may be the same, or may be different, and the depths may be the maximum size in a direction perpendicular to the display substrate.

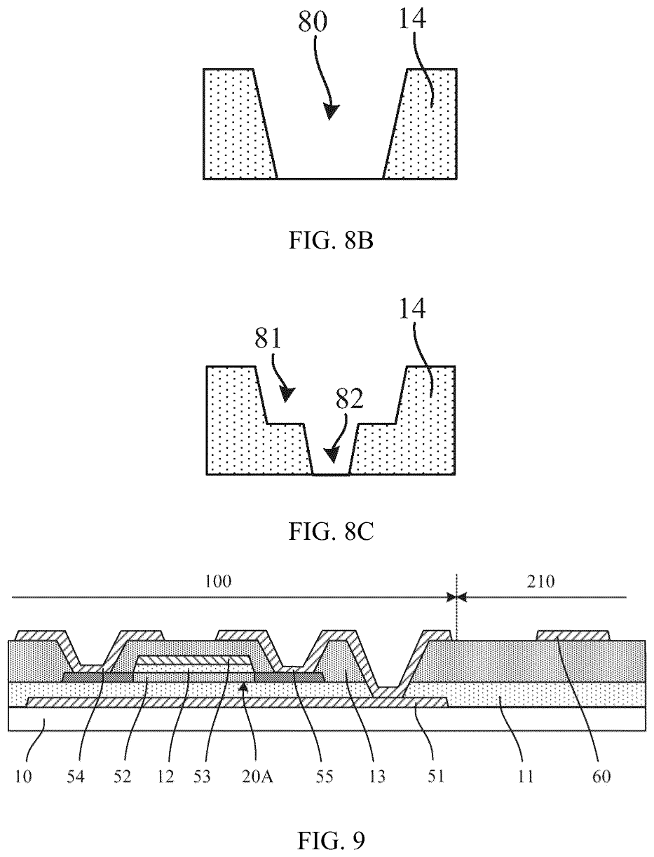

FIG. 8A to FIG. 8C are schematic diagrams of a sectional structure of the groove according to an exemplary embodiment of the present disclosure, which are sectional views taken along B-B in FIG. 9. In an exemplary implementation, on a plane perpendicular to the display substrate, a sectional shape of the groove 80 may be rectangular, trapezoidal or polygonal, and the rectangular inner wall may be a straight line, a polyline, or an arc.

In an exemplary implementation, the depth of the groove 80 may be less than a thickness of the fourth insulation layer 14, that is, the groove 80 is a blind hole opened in the fourth insulation layer 14, as shown in FIG. 8A.

In an exemplary implementation, the depth of the groove 80 may be equal to a thickness of the fourth insulation layer 14, that is, the groove 80 is a through hole opened in the fourth insulation layer 14, as shown in FIG. 8B.

In an yet another exemplary implementation, the groove may at least include a first groove 81 and a second groove 82 which are communicated, wherein the second groove 82 is arranged on a groove bottom of the first groove 81, an area of the second groove 82 is smaller than an area of the first groove 81, and an orthographic projection of the second groove 82 on the substrate is located within an range of an orthographic projection of the first groove 81 on the substrate, forming a stepped groove structure, as shown in FIG. 8C.

Exemplary description is made below through a preparation process of a display substrate. A “patterning process” mentioned in the present disclosure includes coating with a photoresist, mask exposure, development, etching, photoresist stripping, and other treatments for a metal material, an inorganic material, or a transparent conductive material, and includes coating with an organic material, mask exposure, development, and other treatments for an organic material. Deposition may be any one or more of sputtering, evaporation, and chemical vapor deposition. Coating may be any one or more of spray coating, spin coating, and ink-jet printing. Etching may be any one or more of dry etching and wet etching, which is not limited in present disclosure. A “thin film” refers to a layer of thin film made through a material on a substrate through a process such as deposition, coating, etc. If the “thin film” does not need a patterning process in an entire preparation process, the “thin film” may also be called a “layer”. If the “thin film” needs a patterning process in an entire preparation process, it is called a “thin film” before the patterning process, and called a “layer” after the patterning process. The “layer” after the patterning process includes at least one “pattern”. “A and B being arranged in a same layer” mentioned in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B is located within a range of an orthographic projection of A” refers to a boundary of the orthographic projection of B falling within a range of a boundary of the orthographic projection of A, or a boundary of the orthographic projection of A is overlapped with a boundary of the orthographic projection of B.

In an exemplary implementation, the preparation process of the display substrate may include following operations.

(1) A pattern of a circuit layer of a transistor is prepared on the substrate. In an exemplary implementation, preparing the circuit layer of the transistor on the substrate may include following operations.

A first conductive thin film on the substrate 10 is deposited, and the first conductive thin film is patterned by a patterning process to form a pattern of a first conductive line layer arranged on the substrate 10, wherein the first conductive layer at least includes a shielding electrode 51 located in the display region 100.

Then, a first insulation thin film and a semiconductor thin film are sequentially deposited on the substrate where the aforementioned patterns, and the semiconductor thin film is patterned by a patterning process to form a first insulation layer 11 covering the pattern of the shielding electrode and form a pattern of a semiconductor layer arranged on the first insulation layer 11, wherein the pattern of the semiconductor layer at least includes an active layer 52 located in the display region 100, and an orthographic projection of the active layer 52 on the substrate is located within an range of an orthographic projection of the shielding electrode 51 on the substrate.

Then, a second insulation thin film and a second conductive thin film are sequentially deposited on the substrate where the aforementioned patterns, the second conductive thin film and the second insulation thin film are patterned by a patterning process to form a second insulation layer 12 arranged on the pattern of the semiconductor layer and form a pattern of a second conductive layer arranged on the second insulation layer 12, wherein the pattern of the second conductive layer at least includes a gate electrode 53 located in the display region 100, an orthographic projection of the pattern of the second conductive layer on the substrate is located within an range of an orthographic projection of the second insulation layer 12 on the substrate, and an orthographic projection of the gate electrode 53 on the substrate is located within an range of the orthographic projection of the active layer 52 on the substrate.

Then, a doped processing on the active layer 52 is performed by shielding using the gate electrode 53 so that the active layer 52 forms a channel region and doped regions located on both sides of the channel region.

In an exemplary implementation, the second conductive layer pattern may also include a structure such as gate traces, which is not limited in the present disclosure.

Then, a third insulation thin film is deposited on the substrate where the aforementioned patterns, and the third insulation thin film is patterned by a patterning process to form a third insulation layer 13 covering the pattern of the second conductive layer, wherein the third insulation layer 13 in the display 100 is provided with patterns of two active vias and at least one barrier via. The two active vias may be located in doped regions on both sides of the active region 52, the third insulation layer 13 within the active via is etched to expose surfaces of both sides of the active layer 52, at least one barrier via may be located on an edge of the shielding electrode 51, and the third insulation layer 13 and the first insulation layer 11 within the barrier via are etched to expose a surface of the shielding electrode 51.

Then, a third conductive thin film is deposited on the substrate where the aforementioned patterns, and the third conductive thin film is patterned by a patterning process to form a pattern of a third conductive layer on the third insulation layer 13, wherein the pattern of the third conductive layer at least includes a source electrode 54 and a drain electrode 55 which are located in the display region 100, and a power supply electrode 60 located in the transition region 210. The source electrode 54 and the drain electrode 55 are respectively connected to the doped regions on both sides of the active region 52 through the active vias, and the drain electrode 55 is also connected to the shielding electrode 51 through the barrier via.

So far, the pattern of the transistor circuit layer prepared on the substrate 10 has been finished, as illustrated in FIG. 9. In an exemplary implementation, the shielding electrode 51, the active layer 52, the gate electrode 53, the source electrode 54 and the drain electrode 55 constitute a transistor 20A, and the power supply electrode 60 may serve as an electrode for transmitting a low-voltage power supply signal. In an exemplary implementation, the transistor 20A may be a drive transistor in a pixel drive circuit, and the drive transistor may be a thin film transistor.

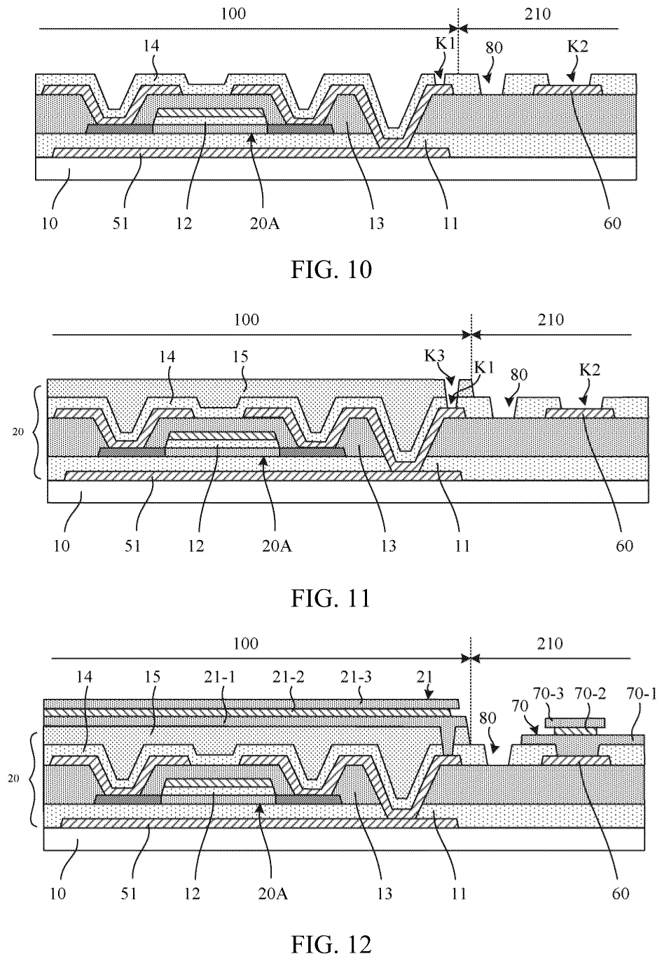

(2) A pattern of a fourth insulation layer is formed. In an exemplary implementation, forming of the pattern of the fourth insulation layer may include: depositing a fourth insulation thin film on the substrate on which the aforementioned patterns are formed, and patterning the fourth insulation thin film through a patterning process to form a fourth insulation layer 14 covering the pattern of the third conductive layer, wherein the fourth insulation layer 14 is provide with a first via K1, a second via K2 and at least one groove 80, as shown in FIG. 10.

In an exemplary implementation, the first via K1 may be arranged in the display region 100, the fourth insulation thin film within the first via K1 is etched away to expose a surface of a drain electrode of the transistor 20A, and the first via K1 is configured such that the anode formed subsequently is connected with the drain electrode of the transistor 20A through the first via K1.

In an exemplary implementation, the second via K2 may be arranged in the transition region 210, the fourth insulation thin film within the second via K2 is etched away to expose a surface of the power supply electrode 60, and the second via K2 is configured such that the auxiliary cathode formed subsequently is connected with the power supply electrode 60 through the second via K2.

In an exemplary implementation, the groove 80 may be arranged in the transition region 210, and is configured to be filled with a pixel definition layer which is formed subsequently to increase the contact area between the pixel definition layer and the fourth insulation layer 14 to improve an adhesion force between the pixel definition layer and the fourth insulation layer.

In an exemplary implementation, an area of an orthographic projection of the groove 80 on the substrate may be larger than an area of an orthographic projection of the first via K1 on the substrate to ensure better adhesion of the pixel definition layer which is formed subsequently to improve an adhesion force between the pixel definition layer and the fourth insulation layer.

In an exemplary implementation, the groove 80 may be a blind hole structure, and a portion of the thickness of the fourth insulation thin film within the groove 80 is etched away, so that a portion of the thickness of the fourth insulation layer is remained on the bottom of the groove 80.

In another exemplary implementation, the groove 80 may be a through-hole structure 80, and all of the thickness of the fourth insulation thin film within the groove 80 is etched away, so that the groove 80 exposes a surface of the third insulation layer 13.

In an exemplary implementation, on a plane parallel to the display substrate, a shape of the groove 80 may include any one or more of the following: triangle, rectangle, polygon, circle and ellipse.

In an exemplary implementation, on a plane perpendicular to the substrate, a sectional shape of the groove 80 may be rectangular, trapezoidal or polygonal, and the rectangular inner wall may be a straight line, a polyline, or an arc.

In exemplary implementation, when a plurality of grooves 80 are arranged in the transition region 210, shapes of the plurality of grooves 80 may be the same, or may be different. Width of the plurality of grooves 80 may be same, or may be different. Lengths of the plurality of grooves 80 may be same, or may be different. Depth of the plurality of grooves 80 may be same, or may be different.

(3) A pattern of a first planarization layer is formed. In an exemplary implementation, forming the pattern of the first planarization layer may include: coating a first planarization thin film on the substrate where the aforementioned patterns are formed, patterning the first planarization thin film through a patterning process to form a first planarization layer 15 on the fourth insulation layer 14, wherein the first planarization layer 15 is provided with a third via K3, as shown in FIG. 11.

In an exemplary implementation, the first planarization layer 15 may be located in the display region 100, and the first planarization thin film of the transparent region is removed to expose a fourth insulation layer 14, and a groove 80 and a second via K2 provided on the fourth insulation layer 14 to increase a transparency of the transparent region.

In an exemplary implementation, the third Via K3 may be provided in the display region 100, and a first planarization thin film within the third via K3 is removed to expose a first via K1, so that the third via K3 and the first via K1 are communicated, and the first via K1 and the third via K3 which are communicated constitute an anode via.

In an exemplary implementation, an area of an orthographic projection of the groove on the substrate may be larger than an area of an orthographic projection of the anode via on the substrate to ensure better adhesion of the pixel definition layer which is formed subsequently to improve an adhesion force between the pixel definition layer and the fourth insulation layer.

So far, the pattern of the drive structure layer 20 prepared on the base 10 is finished, as shown in FIG. 11. In an exemplary implementation, the drive structure layer 20 of the display region 100 may at least include a first conductive layer, a first insulation layer 11, a semiconductor layer, a second insulation layer 12, a second conductive layer, a third insulation layer 13, a third conductive layer, a fourth insulation layer 14, and a planarization layer 15 which are arranged sequentially on the substrate, wherein the fourth insulation layer 14 and the planarization layer 15 are provided with anode vias. The drive structure layer 20 of the transition region 210 may at least include a first insulation layer 11, a second insulation layer 12, a third insulation layer 13, a power supply electrode 60 and a fourth insulation layer 14 which are arranged sequentially on the substrate, wherein the fourth insulation layer 14 is provided with a second via and at least one groove, and the second via K2 exposes a power supply electrode 60.

In an exemplary implementation, the substrate may be a flexible substrate, or may be a rigid substrate. The rigid substrate include glass or quartz, etc., and the flexible substrate may include a first flexible material layer, a first inorganic material layer, a second flexible material layer and a second inorganic material layer which are stacked. In an exemplary implementation, a material of the first flexible material layer and the second flexible material layer may be Polyimide (PI), Polyethylene Terephthalate (PET), or a Polymer soft film subjected to a surface treatment, etc., a material of the first inorganic material layer and the second inorganic material layer may be Silicon Nitride (SiNx) or Silicon Oxide (SiOx), etc., and the first inorganic material layer and the second inorganic material layer may also be called Barrier layers.

In an exemplary implementation, the first insulation layer, the second insulation layer, the third insulation layer, and the fourth insulation layer may be made through any one or more of Silicon Oxide (SiOx), Silicon Nitride (SiNx), and Silicon Oxynitride (SiON), and may be a single layer, a multi-layer, or a composite layer. The first insulation layer is referred to as a buffer layer, the second insulation layer is referred to as a gate insulation (GI) layer, the third insulation layer is referred to as an interlayer dielectric (ILD) layer, and the fourth insulation layer is referred to as a passivation (PVX) layer. The first planarization layer may be made through an organic material such as resin. The first conductive layer, the second conductive layer, and the third second conductive layer may be made through a metal material, such as any one or more of Argentum (Ag), Copper (Cu), Aluminum (Al), Titanium (Ti), and Molybdenum (Mo), or an alloy material of the above metals, such as an Aluminum Neodymium alloy (AlNd) or a Molybdenum Niobium alloy (MoNb), and may be of a single-layer structure, or a multi-layer composite structure, such as Ti/Al/Ti. The semiconductor layer may be made through various materials, such as amorphous Indium Gallium Zinc Oxide (a-IGZO), Zinc Oxynitride (ZnON), Indium Zinc Tin Oxide (IZTO), amorphous Silicon (a-Si), polycrystalline Silicon (p-Si), hexathiophene, and polythiophene. That is, the present disclosure is applicable to a transistor manufactured based on an oxide technology, a silicon technology, and an organic matter technology.

(4) A pattern of an anode conductive layer is formed. In an exemplary implementation, forming the pattern of the anode conductive layer may include: sequentially depositing a first transparent conductive thin film, a reflective thin film and a second transparent conductive thin film on the substrate where the aforementioned patterns are formed, and patterning the first transparent conductive thin film, the reflective thin film and the second transparent conductive thin film by a patterning process to form the pattern of the anode conductive layer, wherein the pattern of the anode conductive layer at least include an anode 21 and an auxiliary cathode 70, as shown in FIG. 12.

In an exemplary implementation, the anode 21 may be located in the display region 100, the anode 21 may include a first anode 21-1 arranged on the planarization layer 15, a second anode 21-2 arranged on a side of the first anode 21-1 away from the substrate, and a third anode 21-3 arranged on a side of the second anode 21-2 away from the substrate, wherein the first anode 21-1 is connected to a drain electrode of the transistor 20A through an anode via, the second anode 21-2 is lapped with the first anode 21-1, and the third anode 21-3 is lapped with the second anode 21-2.

In an exemplary implementation, the auxiliary cathode 70 may be located in transition region 210, the auxiliary cathode 70 may include a first auxiliary cathode 70-1 arranged on the fourth insulation layer 14, a second auxiliary cathode 70-2 arranged on a side of the first auxiliary cathode 70-1 away from the substrate, and a third auxiliary cathode 70-3 arranged on a side of the second auxiliary cathode 70-2 away from the substrate, wherein the first auxiliary cathode 70-1 is connected to the power supply electrode 60 through the second via K2, the second auxiliary cathode 70-2 is lapped with the first auxiliary cathode 70-1, and the third auxiliary cathode 70-3 is lapped with the second auxiliary cathode 70-2.

In an exemplary implementation, the auxiliary cathode 70 may be arranged on a side of the groove 80 away from the display region 100.

In an exemplary implementation, the first transparent conductive thin film and the second transparent conductive film may be made through metal materials, such as indium tin oxide (ITO) or the like, and the reflective thin layer may be made through metal materials, such as aluminum (Al) or the like.

In an exemplary implementation, the anode 21 and the auxiliary cathode 70 may be formed using repeated wet etching processes. For example, after the first transparent conductive thin film, the reflective thin layer and the second transparent conductive film are deposited sequentially, a layer of photoresist is coated, and after a pattern of the photoresist is formed by masking, exposing and developing the photoresist, a first etchant may be firstly used to etch the second transparent conductive film which is not covered by the photoresist to form the third anode 21-3 and the third auxiliary cathode 70-3. Then, a second etchant is used to etch a reflective thin film which is exposed to form the second anode 21-2 and the second auxiliary cathode 70-2. Then, a third etchant is used to etch a first transparent thin film which is exposed to form the first anode 21-1 and the first auxiliary cathode 70-1. When the second etchant is used to etch the reflective film, by etching the reflective film with a large amount of over-etching, the second auxiliary cathode 70-2 has a large amount of retraction, so that the first auxiliary cathode 70-1 and the third auxiliary cathode 70-3 have protrusions with respect to a side wall of the second auxiliary cathode 70-2, and the upper and lower protrusions and the side wall of the second auxiliary cathode 70-2 form a recessed structure, so that the sectional shapes of the first auxiliary cathode 70-1, the second auxiliary cathode 70-2 and the third auxiliary cathode 70-3 which are stacked have a “ [symbol] ”-shaped structure.

In the exemplary implementation, since the second anode 21-2 and the second auxiliary cathode 70-2 are formed synchronously by the same etching process, the second anode 21-2 also has a large amount of retraction, so that the first anode 21-1 and the third anode 21-3 have protrusions with respect to the sidewall of the second anode 21-2.

Since the third anode 21-3 and the third auxiliary cathode 70-3 are etched simultaneously when the first transparent conductive film is etched by the etchant, the width of the third anode 21-3 formed after etching is smaller than that of the first anode 21-1, and the width of the third auxiliary cathode 70-3 formed after etching is smaller than that of the first auxiliary cathode 70-1.

In an exemplary implementation, an orthographic projection of the second anode 21-2 on the substrate may be within a range of an orthographic projection of the first anode 21-1 on the substrate, the orthographic projection of the second anode 21-2 on the substrate may be within a range of an orthographic projection of the third anode 21-3 on the substrate, and the orthographic projection of the third anode 21-3 on the substrate may be within the range of the orthographic projection of the first anode 21-1 on the substrate.

In an exemplary implementation, an orthographic projection of the second auxiliary cathode 70-2 on the substrate may be within a range of an orthographic projection of the first auxiliary cathode 70-1 on the substrate, and the orthographic projection of the second auxiliary cathode 70-2 on the substrate may be within a range of an orthographic projection of the third auxiliary cathode 70-3 on the substrate.

In an exemplary implementation, an orthographic projection of the third auxiliary cathode 70-3 on the substrate may be located within a range of an orthographic projection of the first auxiliary cathode 70-1, on the base, so that auxiliary cathode 70 has an overall shape with a small upper portion and a large lower portion.

In an exemplary implementation, on a plane perpendicular to the substrate, a sectional shape of the second auxiliary cathode may be a trapezoid.

In an exemplary implementation, the first etchant and the third etchant may adote a dilute H2SO4-based acid, the second etchant may adote a concentrated H3PO4-based acid, and the rate at which the second etchant etches the reflective film is greater than the rate at which the second etchant etches the first transparent conductive film and the second transparent conductive film.

In an exemplary implementation, after this process, the first transparent conductive film, the reflective film, and the second transparent conductive film in the region other than the auxiliary cathode 70 in the transparent region are removed, and the fourth insulation layer 14 and the groove 80 opened in the fourth insulation layer 14 are exposed.

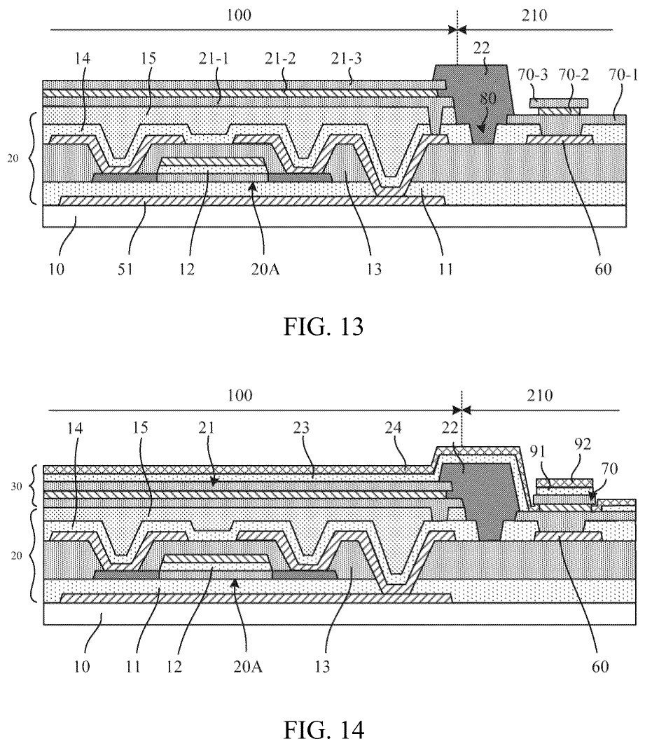

(5) A pattern of a pixel definition layer is formed. In an exemplary implementation, the forming the pattern of the pixel definition layer may include: a pixel definition thin film is coated on the substrate on which the aforementioned patterns are formed; the pixel definition thin film is patterned through a patterning process, so as to form a pattern of a pixel definition (PDL) layer 22, as shown in FIG. 13.

In an exemplary implementation, the pixel definition layer 22 may be located in the display region 100, and the pixel definition thin film of the transparent region is removed to increase a transparency of the transparent region.

In an exemplary implementation, the pixel definition layer 22 of the display region 100 is provided with a pixel opening, and the pixel definition layer within the pixel opening is removed to expose a surface of the third anode 21-3 of the anode 21.

In an exemplary implementation, an orthographic projection of pixel opening on the substrate is located within a range of an orthographic projection of the first anode 21-1, the second anode 21-2 and the third anode 21-3 on the substrate.

In an exemplary implementation, on a plane parallel to the display substrate, a shape of the pixel opening may be a triangle, a rectangle, a polygon, a circle, an ellipse, or the like. On a plane perpendicular to the display substrate, a sectional shape of the pixel opening may be a rectangle, a trapezoid, or the like.

In an exemplary implementation, the pixel definition layer 22 of the display region 100 is arranged on a planarization layer 15 in a region other than the anode 21 and is in direct contact with the planarization layer 15.

In an exemplary implementation, an edge of the planarization layer 15 of the display region close to a side of the transparent region is covered by the pixel definition layer 22.

In an exemplary implementation, a pixel definition layer 22 of the display region extends to the transparent region, and is arranged on a side of the fourth insulation layer 14 away from the substrate and is in contact with the fourth insulation layer 14. A pixel definition layer 22 extending to the transparent region fills the groove 80, which increases a contact area between the pixel definition layer 22 and the fourth insulation layer 14 on the one hand, improving an adhesion force between the pixel definition layer and the fourth insulation layer, and enables a thickness of the pixel definition layer 22 in the transparent region to be larger than that in the display region on the other hand. The increase in the thickness of the pixel definition layer can enhance the ability of the pixel definition layer to resist detaching, which may further improve the adhesion force between the pixel definition layer and the fourth insulation layer.

In an exemplary implementation, the groove 80 is a through-groove structure that penetrates through the fourth insulation layer 14, so that the pixel definition layer 22 filling the groove 80 is in contact with the third insulation layer (interlayer insulation layer).

In an exemplary implementation, an edge of the pixel definition layer 22 on a side away from the display region 100 covers an edge of the auxiliary cathode 70 on a side close to the display region 100.

In an exemplary implementation, an edge of the pixel definition layer 22 on a side away from the display region 100 covers an edge of the first auxiliary cathode 70-1 of the auxiliary cathodes 70 on a side close to the display region 100.

In an exemplary implementation, the pixel definition layer may be made through polyimide, acrylic, polyethylene terephthalate, or the like.

(6) Patterns of an organic light-emitting layer and a cathode are formed. In an exemplary implementation, evaporating an organic light-emitting material on the substrate where the aforementioned patterns are formed to form patterns of the organic light-emitting layer 23 and the light-emitting block 91, and then depositing a cathode thin film on the substrate where the aforementioned patterns are formed to form patterns of the cathode 24 and the cathode block 92, as shown in FIG. 14.

In an exemplary implementation, the organic light-emitting layer 23 and the cathode 24 may be located in the display region 100, the light-emitting block 91 and the cathode block 92 may be located in the transition region 210, the light-emitting block 91 is arranged in isolation from the organic light-emitting layer 23, and the cathode 24 is arranged in isolation from the cathode block 92.

In an exemplary implementation, the organic light-emitting layer 23 of the display region 100 may be connected to the anode 21 through a pixel opening, the cathode 24 may be an integral structure communicated together, and the cathode 24 is lapped on a side of the organic light-emitting layer 23 away from the substrate.

In an exemplary implementation, due to a structure with a shape like a Chinese character “ [symbol] ” of the auxiliary cathode 70, the third auxiliary cathode 70-3 protrudes from the second auxiliary cathode 70-2 for a certain distance, and due to a poor diffusion performance of the organic light-emitting material in the evaporation, thus an “eave” structure of the third auxiliary cathode 70-3 may cut off the light-emitting material, which may not only enables the light-emitting material to be disconnected at a side surface of the third auxiliary cathode 70-3, but also prevent the organic light-emitting material from diffusing to a lower part of the eave, and only form a light-emitting block 91 on a upper surface of the third auxiliary cathode 70-3, thus achieving the mutual isolation between the organic light-emitting layer 23 and the light-emitting block 91.

In an exemplary implementation, due to a structure with a shape like a Chinese character “ [symbol] ” of the auxiliary cathode 70, the third auxiliary cathode 70-3 protrudes from the second auxiliary cathode 70-2 for a certain distance, so that an “eaves” structure of the third auxiliary cathode 70-3 can cut off the cathode film and form a cathode block 92 on the upper surface of the light-emitting block 91.

In an exemplary implementation, an orthographic projection of the light-emitting block 91 on the substrate may be within a range of an orthographic projection of the third auxiliary cathode 70-3 on the substrate, and an orthographic projection of the cathode block 92 on the substrate may be within a range of an orthographic projection of the light-emitting block 91 on the substrate.

In an exemplary implementation, the organic light-emitting layer may include an light-emitting layer (EML), and any one or more of following layers: a hole injection layer (HIL), a hole transport layer (HTL), an electron block layer (EBL), a hole block layer (HBL), an electron transport layer (ETL), and an electron injection layer (EIL). In an exemplary implementation, the organic light-light-emitting material may be formed by evaporation using a Fine Metal Mask (FMM) or an open mask, or by an ink jet process.

In an exemplary implementation, the organic light-emitting layer may be prepared through a following preparation method. First, a hole injection layer and a hole transport layer are sequentially evaporated by using an open mask, and a common layer of the hole injection layer and the hole transport layer is formed on the display substrate. Then, by using a fine metal mask, an electron block layer and a red light-emitting layer are evaporated in a red sub-pixel, an electron block layer and a green light-emitting layer are evaporated in a green sub-pixel, and an electron block layer and a blue light-emitting layer are evaporated in a blue sub-pixel. Electron block layers and light-emitting layers of adjacent sub-pixels may be overlapped slightly (for example, an overlapping portion accounts for less than 10% of an region of a pattern of a respective light-emitting layer), or may be isolated. Then, a hole block layer, an electron transport layer, and an electron injection layer are sequentially evaporated by using an open mask, and a common layer of the hole block layer, the electron transport layer, and the electron injection layer is formed on the display substrate.

In an exemplary implementation, an electron block layer may be used as a micro-cavity adjustment layer of a light-emitting device. By designing a thickness of an electron block layer, a thickness of an organic light-emitting layer between a cathode and an anode may satisfy a design for a length of a micro-cavity. In some exemplary implementations, a hole transport layer, a hole block layer, or an electron transport layer in an organic light-emitting layer may be used as a micro-cavity adjustment layer of a light-emitting device, which is not limited in the present disclosure.

In an exemplary implementation, a light-emitting layer may include a host material and a dopant material doped into the host material. A doping ratio of the dopant material of the light-emitting layer is 1% to 20%. Within a range of the doping ratio, on one hand, the host material of the light-emitting layer may effectively transfer exciton energy to the dopant material of the light-emitting layer to excite the dopant material of the light-emitting layer to emit light; on the other hand, the host material of the light-emitting layer “dilutes” the dopant material of the light-emitting layer, thus effectively improving fluorescence quenching caused by collisions between molecules of the dopant material of the light-emitting layer and collisions between energies, and improving a luminous efficiency and device life. In an exemplary implementation, the doping ratio refers to a ratio of a mass of the dopant material to a mass of the light-emitting layer, that is, a mass percentage. In an exemplary implementation, the host material and the dopant material may be co-evaporated through a multi-source evaporation process, so that the host material and the dopant material are uniformly dispersed in the light-emitting layer. A doping ratio may be adjusted by controlling an evaporation rate of the dopant material or by controlling an evaporation rate ratio of the host material to the dopant material during an evaporation process. In an exemplary implementation, a thickness of the light-emitting layer may be about 10 nm to 50 nm.

In an exemplary implementation, a hole injection layer may be made through an inorganic oxide, such as molybdenum oxide, titanium oxide, vanadium oxide, rhenium oxide, ruthenium oxide, chromium oxide, zirconium oxide, hafnium oxide, tantalum oxide, silver oxide, tungsten oxide, or manganese oxide, or may be made through a p-type dopant of a strongly electron withdrawing system and a dopant of a hole transport material. In an exemplary implementation, a thickness of the hole injection layer may be about 5 nm to 20 nm.

In an exemplary implementation, a hole transport layer may be made through a material with a relatively high hole mobility, such as an aromatic amine compound, and its substituent group may be carbazole, methylfluorene, spirofluorene, dibenzothiophene, or furan. In an exemplary implementation, a thickness of the hole transport layer may be about 40 nm to 150 nm.

In an exemplary implementation, a hole block layer and an electron transport layer may be made through aromatic heterocyclic compounds, such as benzimidazole derivatives, imidazopyridine derivatives, benzimidazophenanthridine derivatives, and other imidazole derivatives; pyrimidine derivatives, triazine derivatives, and other azine derivatives; quinoline derivatives, isoquinoline derivatives, phenanthroline derivatives, and other compounds containing a nitrogen-containing six-membered ring structure (also including compounds having a phosphine oxide-based substituent on a heterocyclic ring). In an exemplary implementation, a thickness of the hole block layer may be about 5 nm to 15 nm, and a thickness of the electron transport layer may be about 20 nm to 50 nm.

In an exemplary implementation, an electron injection layer may be made through an alkali metal or a metal, such as lithium fluoride (LiF), ytterbium (Yb), magnesium (Mg), or Calcium (Ca), or a compound of these alkali metals or metals. In an exemplary implementation, a thickness of the electron injection layer may be about 0.5 nm to 2 nm.

In an exemplary implementation, the cathode thin film may be made through transparent indium zinc oxide (IZO), and may be deposited by a magnetron sputter. Due to the good diffusion performance of indium zinc oxide deposited by the magnetron sputter, thus indium zinc oxide may bypass the “eaves” structure of the third auxiliary cathode and diffuse to the lower part of the eaves, and lap with a side wall of the auxiliary cathode, thus realizing a lap between the cathode and the auxiliary cathode. Moreover, the contact area between the cathode and the auxiliary cathode is large, which can effectively reduce a resistance at the contact interface and improve connection reliability.

So far, preparation of the pattern of the light-emitting structure layer 30 is completed on the drive structure layer 20. The light-emitting structure layer 30 includes an anode, a pixel definition layer, an organic light-emitting layer, a cathode and an auxiliary cathode, wherein the organic light-emitting layer is respectively connected with the anode and the cathode, and the cathode is connected with the auxiliary cathode.

In an exemplary implementation, the preparation process of the display substrate may also include forming a pattern of an encapsulation structure layer, and forming a pattern of the encapsulation structure layer may include: firstly, using an open mask plate to deposit a first inorganic film by means of plasma enhanced chemical vapor deposition (PECVD) to form the first encapsulation layer. Then, ink-jet printing is performed on an organic material on the first encapsulation layer through an ink-jet printing process, and a second encapsulation layer is formed after curing. and then depositing a second inorganic thin film by using an open mask to form a third encapsulation layer, wherein the first encapsulation layer, the second encapsulation layer and the third encapsulation layer form the encapsulation layer. In an exemplary embodiment, the first encapsulation layer and the third encapsulation layer may be made through any one or more of silicon oxide (SiOx), silicon nitride (SiNx), and silicon nitride (SiON), and each may be in a single-layer structure, a multi-layer structure, or a composite layer structure; the second encapsulation layer may be made through a resin material, thereby forming a stacked structure of inorganic material/organic material/inorganic material, wherein the organic material layer is arranged between the two inorganic material layers, thus ensuring that the external water vapor cannot enter the light-emitting structure layer.

In an exemplary implementation, after preparation of the encapsulation structure layer is completed, a Touch Structure layer (TSP) may be formed on THE encapsulation structure layer, and the touch structure layer may include a touch electrode layer, or include a touch electrode layer and a touch insulation layer, which is not limited in the present disclosure.

At present, transparent display apparatuses using display region and transparent region have the problem of poor pixel dark spots. The research shows that the poor dark spots of pixels are caused by the short circuit between cathode and anode. Further research shows that the short circuit between cathode and anode is caused by the detachment of the pixel definition layer in the transition region. In the transparent region, since the pixel definition layer is in direct contact with the fourth insulation layer, and the adhesion force between the pixel definition layer of an organic material and the fourth insulation layer of an inorganic material is poor, thus the pixel definition layer may detach. When the pixel definition layer detaches, the cathode formed subsequently will lap with the anode, which results in a short circuit between the cathode and the anode, thus causing poor pixel dark spots.

An exemplary embodiment of the present disclosure provide a display substrate, by arranging a groove on the fourth insulation layer of the transparent region, a pixel definition layer directly contacting with the fourth insulation layer is made to fill the groove, which increases the contact area between the pixel definition layer and the fourth insulation layer, thus enhancing the adhesion force between the pixel definition layer and the fourth insulation layer and preventing the pixel definition layer from detaching. In addition, the pixel definition layer filling the groove is equivalent to increasing a thickness of the pixel definition layer, thus enhancing an ability of the pixel definition layer to resist detaching, which may further improve an adhesion force between the pixel definition layer and the fourth insulation layer, and further avoid the detachment of the pixel definition layer. The display substrate of the exemplary embodiment of the present disclosure may prevent the pixel definition layer from detaching and may effectively avoid the short circuit between the cathode and the anode, thus effectively avoiding the poor pixel dark spots.

The exemplary embodiments of the present disclosure may effectively increase the contact area between the pixel definition layer and the fourth insulation layer by setting the number of grooves, the planar shape and the sectional shape. Since the groove on the fourth insulation layer and the via on the fourth insulation layer according to the present disclosure are formed synchronously, the scheme of the invention does not increase additional patterning process and preparation cost, and has good process compatibility, simple process realization, easy implementation, high production efficiency, low production cost and high yield.

By setting the sectional shape of the auxiliary cathode to a shape like a Chinese character “ [symbol] ” according to exemplary embodiments of the present disclosure, the organic light-emitting layer and cathode are made to be disconnected at the edge of the auxiliary cathode, and the cathode is deposited by magnetron sputter, which not only smoothly achieves the lap between the cathode and the auxiliary cathode, but also effectively increases the contact area between the cathode and the auxiliary cathode, effectively reduces the resistance at the contact interface, improves the connection reliability and improves the display quality.

The structure of the display substrate and the preparation process thereof in the exemplary embodiments of the present disclosure are merely illustrative. In an exemplary implementation, a corresponding structure may be changed and a patterning process may be increased or decreased according to actual needs, which is not limited in the present disclosure.

In an exemplary implementation, the display substrate of the present disclosure may be applied to a display apparatus with a pixel drive circuit, such as an OLED, a quantum dot display (QLED), a light-emitting diode display (Micro LED or Mini LED) or a quantum dot light-emitting diode display (QDLED), etc., which is not limited here in the present disclosure.

The present disclosure further provides a preparation method of a display substrate for preparing the aforementioned display substrates. In an exemplary implementation, the display substrate includes a display region and a transparent region, wherein the display region is configured to achieve image display, and the transparent region is configured to make light pass through; the preparation method for the display substrate may include:
forming a drive structure layer on the substrate, wherein the drive structure layer at least comprises an inorganic insulation layer, the drive structure layer of the display region further comprises a planarization layer arranged on a side of the inorganic insulation layer away from the substrate, and at least one groove is arranged on the inorganic insulation layer in the transparent region; and
forming a light-emitting structure layer on the drive structure layer, wherein the light-emitting structure layer at least includes a pixel definition layer, the pixel definition layer is arranged on a side of the planarization layer away from the substrate and is in contact with the planarization layer, and the pixel definition layer fills a groove located in the transparent region.

Although the implementations disclosed in the present disclosure are as above, the described contents are only implementation used for convenience of understanding the present disclosure and are not intended to limit the present disclosure. Any skilled in the art to which the present disclosure pertains, without departing from the spirit and scope disclosed in the present disclosure, may make any modifications and changes in a form and details of implementations. However, the scope of patent protection of the present application should still be subject to the scope defined by the appended claims.

1. A display substrate, comprising a display region and a transparent region, wherein the display region is configured to achieve image display, and the transparent region is configured to make light pass through; on a plane perpendicular to the display substrate, the display substrate at least comprises a drive structure layer arranged on a substrate and a light-emitting structure layer arranged on a side of the drive structure layer away from the substrate, wherein the drive structure layer at least comprises an inorganic insulation layer, and the light-emitting structure layer at least comprises a pixel definition layer; the drive structure layer of the display region further comprises a planarization layer arranged on a side of the inorganic insulation layer away from the substrate, and the pixel definition layer is arranged on a side of the planarization layer away from the substrate and is in contact with the planarization layer; at least one groove is arranged on the inorganic insulation layer of the transparent region, and the pixel definition layer fills the groove located in the transparent region.

2. The display substrate according to claim 1, wherein a thickness of the pixel definition layer of the transparent region is greater than a thickness of the pixel definition layer in the display region.

3. The display substrate according to claim 1, wherein a depth of the groove is less than a thickness of the inorganic insulation layer.

4. The display substrate according to claim 1, wherein a depth of the groove is equal to a thickness of the inorganic insulation layer.

5. The display substrate according to claim 4, wherein the drive structure layer of the transparent region at least comprises a buffer layer arranged on a substrate and an interlayer insulation layer arranged on a side of the buffer layer away from the substrate, and the inorganic insulation layer is arranged on a side of the interlayer insulation layer away from the substrate, and fills the pixel definition layer of the groove and is in contact with the interlayer insulation layer.

6. The display substrate according to claim 1, wherein the groove comprises a first groove and a second groove which are communicated, the second groove is arranged on a groove bottom of the first groove, and an orthographic projection of the second groove on the substrate is located within a range of an orthographic projection of the first groove on the substrate.

7. The display substrate according to claim 1, wherein on a plane parallel to the substrate, a shape of the groove comprises any one or more of the following: triangle, rectangle, polygon, circle and ellipse.

8. The display substrate according to claim 1, wherein on a plane perpendicular to the substrate, a sectional shape of the groove is rectangular, trapezoidal, or polygonal.

9. The display substrate according to claim 1, wherein a plurality of grooves are provided on the inorganic insulation layer, and on a plane parallel to the substrate, shapes of the plurality of grooves are same or different.

10. The display substrate according to claim 1, wherein a plurality of grooves are provided on the inorganic insulation layer, and on a plane parallel to the substrate, sizes of the plurality of grooves are same or different.

11. The display substrate according to claim 1, wherein a plurality of grooves are provided on the inorganic insulation layer, and on a plane perpendicular to the substrate, depths of the plurality of grooves are same or different.

12. The display substrate according to claim 1, wherein an anode via is also provided on the inorganic insulation layer of the display region; on a plane parallel to the substrate, an area of an orthographic projection of the groove on a plane of the substrate is greater than an area of an orthographic projection of the anode via on a plane of the substrate.

13. The display substrate according to claim 1, wherein an auxiliary cathode is also provided on the transparent region, and the auxiliary cathode is arranged on a side of the groove away from the display region.

14. The display substrate according to claim 13, wherein the auxiliary cathode comprises a first auxiliary cathode arranged on a side of the inorganic insulation layer away from the substrate, a second auxiliary cathode arranged on a side of the first auxiliary cathode away from the substrate, and a third auxiliary cathode arranged on a side of the second auxiliary cathode away from the substrate, an orthographic projection of the second auxiliary cathode on the substrate is located within a range of an orthographic projection of the first auxiliary cathode on the substrate, and the orthographic projection of the second auxiliary cathode on the substrate is located within a range of an orthographic projection of the third auxiliary cathode on the substrate.

15. The display substrate according to claim 14, wherein the pixel definition layer covers an edge of the auxiliary cathode close to a side of the display region.

16. A display apparatus, comprising the display substrate according to claim 1.

17. A method for preparing a display substrate, the display substrate comprising a display region and a transparent region, wherein the display region is configured to achieve image display, and the transparent region is configured to make light pass through; the preparing method comprises:
forming a drive structure layer on the substrate, wherein the drive structure layer at least comprises an inorganic insulation layer, the drive structure layer of the display region further comprises a planarization layer arranged on a side of the inorganic insulation layer away from the substrate, and at least one groove is arranged on the inorganic insulation layer in the transparent region; and
forming a light-emitting structure layer on the drive structure layer, wherein the light-emitting structure layer at least comprises a pixel definition layer, the pixel definition layer is arranged on a side of the planarization layer away from the substrate and is in contact with the planarization layer, and the pixel definition layer fills a groove located in the transparent region.
